(19) United States
(12) Patent Application Publication
(10) Pub. No.: US 2009/0003074 A1
(43) Pub. Date: Jan. 1, 2009

(54) Scalable Electrically Eraseable And Programmable Memory (EEPROM) Cell Array

(75) Inventors: Sorin S. Georgescu, San Jose, CA (US); A. Peter Cosmin, Santa Clara, CA (US)

Correspondence Address: BEVER HOFFMAN & HARMS, LLP;2099 Gateway Place, Suite 320, San Jose, CA, 95110, US

(73) Assignee: Catalyst Semiconductor, Inc., Santa Clara, CA (US)

(21) Appl. No.: 12/207,320

(22) Filed: Sep. 9, 2008

Related U.S. Application Data
(63) Continuation-in-part of application No. 11/278,103, filed on Mar. 30, 2006.

(51) Int. Cl. G11C 16/06; H01L 29/788

(52) U.S. Cl. 365/185.18; 257/316; 257/390; 365/185.29; 257/E29.3

(57) ABSTRACT

A non-volatile memory (NVM) system includes a plurality of NVM cells fabricated in a dual-well structure. Each NVM cell includes an access transistor and an NVM transistor, wherein the access transistor has a drain region that is continuous with a source region of the NVM transistor. The drain regions of each NVM transistor in a column of the array are commonly connected to a corresponding bit line. The control gates of each NVM transistor in a row of the array are commonly connected to a corresponding word line. The source regions of each of the access transistors in the array are commonly coupled. The NVM cells are programmed and erased without having to apply the high programming voltage V_{PP} across the gate dielectric layers of the access transistors. As a result, the NVM cells can be scaled down to sub-0.35 micron geometries.

### RELATED APPLICATIONS

This is a continuation-in-part of pending U.S. patent application Ser. No. 11/278,103 filed Mar. 30, 2006, and entitled, “Scalable Electrically Eraseable And Programmable Memory (EEPROM) Cell Array” by Sorin S. Georgescu and A. Peter Cosmin.

### FIELD OF THE INVENTION

The present invention relates to electrically erasable and programmable memory (EEPROM) cells.

### RELATED ART

FIG. 1 is a circuit diagram illustrating a conventional memory system 100 that includes a 2×2 array of electrically erasable and programmable memory (EEPROM) cells 101-104. EEPROM cells 101-104 include CMOS access transistors 111-114, respectively, and non-volatile memory (NVM) transistors 121-124, respectively. The drains of access transistors 111 and 113 are coupled to drain (bit line) terminal D1. Similarly, the drains of access transistors 112 and 114 are coupled to drain (bit line) terminal D2. The sources of access transistors 111-114 are coupled to the drains of NVM transistors 121-124, respectively. The sources of NVM transistors 121-124 are commonly coupled to source terminal S12. The select gates of access transistors 111-112 are commonly connected to select line SL1, and the select gates of access transistors 113-114 are commonly connected to select line SL2. The control gates of NVM transistors 121-122 are commonly connected to control line CL1, and the control gates of NVM transistors 123-124 are commonly connected to control line CL2.

FIG. 2 is a cross sectional view of EEPROM cell 101 and peripheral transistors 201 and 202. Peripheral transistors 201-202 are located on the same chip as EEPROM cells 101-104, and are typically used to access these EEPROM cells. Peripheral transistor 201 includes a source 211, a drain 212, a control gate 210, and a gate dielectric layer 213. Gate dielectric layer 213 has a first thickness T1, which is selected in view of a first voltage used to control the peripheral circuitry. For example, thickness T1 can be 75 Angstroms or less, depending on the process. Similarly, peripheral transistor 202 includes a source 221, a drain 222, a control gate 220, and a gate dielectric layer 223. Gate dielectric layer 223 has a second thickness T2, which is selected in view of a second voltage used to control the peripheral circuitry. For example, thickness T2 can be 300 Angstroms to handle a control voltage of 15 Volts.

Access transistor 111 includes a gate dielectric layer 231 having the second thickness T2. A select gate SG1 is located over this gate dielectric layer 231. NVM transistor 121 includes a gate dielectric layer 232, most of which has a thickness close to the second thickness T2. Dielectric layer 232 includes a thin dielectric tunneling region 233, which has a third thickness T3 of about 100 Angstroms. A floating gate FG1, which stores charge, is located over gate dielectric layer 232 (including tunneling dielectric region 233). The tunneling dielectric region 233 is located over a highly doped N+ region 235, which is an extension of the n-type source/drain diffusion shared by access transistor 111 and NVM transistor 121. An inter-poly dielectric layer 234, having a thickness T4, is located over floating gate FG1. A control gate CG1 is located over the inter-poly dielectric layer 234. The thickness T4 of gate dielectric layer 234 is selected in view of the voltages used to control NVM transistor 121. For example, the dielectric layer 234 can be a composite dielectric (oxide-nitride-oxide) with an equivalent silicon dioxide thickness of about 200 Angstroms to handle programming voltages of about 15 Volts. EEPROM cells 102-104 are identical to EEPROM cell 101.

In order to erase EEPROM cells 101 and 102, a high programming voltage VPP (on the order of about 15 Volts) is applied to the control line CL1 and the select line SL1. The drain terminals D1-D2 and the source terminal S12 are grounded. Under these conditions, the floating gates of NVM transistors 121-122 are coupled to a fraction of the programming voltage VPP, which is enough to produce tunneling currents from the underlying diffusion extension region 235 through the thin gate dielectric region 233. Consequently, the tunneling currents in NVM transistors 121-122, will cause excess electrons to be trapped in the floating gates of these NVM transistors. These trapped electrons increase the threshold voltages of NVM transistors 121-122 (i.e., erase NVM transistors 121-122). EEPROM cells 101-102 can be erased independently of EEPROM cells 103-104. Alternately, EEPROM cells 103-104 can be erased at the same time as EEPROM cells 101-102.

In order to program EEPROM cell 101, the high programming voltage VPP (15 Volts), is applied to the drain terminal D1 and to select line SL1. The control line CL1 and the select line SL2 are grounded. The source terminal S12 and drain D2 are left floating. Under these conditions, access transistor 111 is turned on, and the high programming voltage VPP is applied to the drain extension region 235 of NVM transistor 121. The high voltage across the thin gate dielectric region 233 causes electrons to be removed from the floating gate FG1, thereby causing this transistor to have a relatively low threshold voltage.

The drain of access transistor 111 must have a relatively large active region around the contact in order to properly receive the high programming voltage VPP. In addition, the select gate SG1 of access transistor 111 must be relatively large in order to properly receive the high programming voltage VPP. As a result, access transistor 111 cannot be scaled for processes with feature size of less than 0.35 microns. Similarly, the memory transistor 121 has a large gate area, to accommodate the drain extension diffusion region 235 under the tunneling dielectric region 233. The same limitations apply to access transistors 112-114 and memory transistors 122-124, respectively. It would therefore be desirable to have an EEPROM system that can be scaled to sub-0.35 micron processes.

Recent EEPROM-type systems have attempted to shrink the EEPROM cell by reducing the maximum required bit line or source line voltage from 15-20 Volts to about 5 Volts. These memories have a number of significant drawbacks, including (i) the memory operation is complicated, in one case requiring both positive and negative voltages to be applied to the array, (ii) the processes necessary to implement these memories is are complicated, thus being prone to difficult yield management, and (iii) the EEPROM cell size is relatively large and cannot compensate for the costlier process required to fabricate the EEPROM cell.

It would therefore be desirable to have an improved EEPROM system that is scaleable, and avoids the drawbacks of conventional EEPROM systems.

### SUMMARY

Accordingly, the present invention provides a memory system that includes a column of EEPROM cells, including a first EEPROM cell having a first access transistor and a first NVM transistor, and a second EEPROM cell having a second access transistor and a second NVM transistor. The first access transistor has a drain region that is continuous with the source region of the first NVM transistor, and the second access transistor has a drain region that is continuous with the source region of the second NVM transistor. The first and second access transistors share a common source region. A first bit line connects the drain of the first NVM transistor and the drain of the second NVM transistor. First and second word lines are connected to the control gates of the first and second NVM transistors, respectively. First and second select lines are connected to the control gates of the first and second access transistors, respectively. Multiple columns can be combined to form an array of EEPROM cells.

The EEPROM cells are fabricated in a first well region, which in turn, is located in a second well region of an opposite conductivity type. For example, if the EEPROM cells are made of n-channel access transistors and n-channel NVM transistors, then the EEPROM cells are fabricated in a p-well region. The p-well region, in turn, is located in an n-well region. Bias voltages are applied to the p-well and n-well regions in accordance with one embodiment of the present invention.

To erase the first NVM transistor, the control gate of the first NVM transistor (i.e., the first word line) is grounded, and a programming voltage V_{PP} (e.g., 15 Volts) is applied to the first and second well regions, the first and second select lines, and the second word line (assuming that the second NVM transistor is not to be erased). The first and second bit lines and the source line are left in a floating state. Under these conditions, a tunneling current flows from the first well region to the floating gate of the first NVM transistor, thereby erasing the first NVM transistor. Any other NVM transistors coupled to the first word line are erased at the same time as the first NVM transistor. The second NVM transistor (and any other NVM transistors coupled to the second word line) can be erased at the same time as the first NVM transistor by grounding the second word line during the erase operation.

To program the first EEPROM cell, the programming voltage V_{PP} is applied to the control gate of the first NVM transistor, and the first and second well regions are grounded. The first bit line, which corresponds to the cell selected to be programmed, is also grounded. The control gates of the first and second access transistors and the control gate of the second NVM transistor are grounded. The sources of the first and second access transistors are left in a floating state. Under these conditions, a tunnel current flows from the floating gate of the first NVM transistor to the first well region, thereby programming this NVM transistor. Bit lines associated with columns that are not to be programmed are held at an intermediate voltage to prevent programming of EEPROM cells in these columns.

Advantageously, the high programming voltage is not applied across the gate dielectric layers of the first and second access transistors during erase and program operations of the present invention. Thus, the gate dielectric layers of the first and second access transistors can be made relatively thin. Similarly, the high programming voltage is not applied to the bit lines or to the source lines, with respect to the underlying well. Consequently, the access transistors and the NVM transistors may be scaled to sub-0.35 micron processes.

In accordance with another embodiment of the present invention, the memory system is organized in columns and rows so that memory cells are grouped by two in the column direction and by a byte size in the row direction. Each memory cell includes an access transistor and an NVM transistor, both transistors having the same composition and manufactured with the same process steps. The NVM transistor has a first polysilicon gate (floating gate) on top of a tunnel oxide layer, an inter-gate dielectric layer (e.g., ONO) formed over the first polysilicon gate, and a second polysilicon gate (control gate) formed over the inter-gate dielectric layer. The access transistor has the same construction as the NVM transistor; however, the first polysilicon gate is shorted to the second polysilicon gate in the access transistor. Alternately, the first polysilicon gate may remain floating within the access transistor. In this alternative embodiment, the first polysilicon gate of the access transistor is maintained in a discharged state (i.e. is not subjected to program or erase conditions).

Within each memory cell, the source of the access transistor is connected to the drain of the NVM transistor. The drain of each access transistor in the same column is connected to a first metal bit line, and the source of each NVM transistor in the same column is connected to a second (complementary) metal bit line. The memory cells in each set of columns that defines a byte are fabricated in a corresponding ‘byte’ well region (a p-well region if the cell transistors are n-type devices). Each of these separate ‘byte’ well regions are fabricated in a deep well region of an opposite conductivity type. The ‘byte’ well regions are separated by a minimum space that allows low voltage bias separation (e.g., differential bias less than 5V). All junctions associated with the memory cell transistors are constructed for low voltage operation (e.g., less than 5V), thus allowing for a compact memory.

The gates of the access transistors in each row are commonly connected to form a corresponding row select line. Similarly, the control gates of all NVM transistors in each row are commonly connected to form a corresponding word line. Drain and source regions of the NVM transistors are fabricated as lightly doped (LDD) regions, to minimize hot carrier effects at low voltages (e.g., less than 5V).

To erase a first byte of memory cells, the corresponding word line is grounded, and an erase control voltage V_{E} (e.g., 15 Volts) is applied to the corresponding ‘byte’ well region and the deep well region. All other word lines (of memory cells not to be erased) and all select gates are biased to the erase control voltage V_{E}-All bit lines are left in a floating state. The ‘byte’ well regions associated with other bytes (which are not to be erased) are biased to a voltage equal to the erase control voltage V_{E} minus an erase counter-bias voltage V_{EC}.

Under these conditions, a tunnel current flows from the ‘byte’ well region corresponding with the byte to be erased to the floating gates of the NVM transistors of the byte to be erased, thereby erasing the selected byte. This current is actually composed of electrons (with negative charge) flowing in the opposite direction from floating gate to the ‘byte’ well. Note that only NVM transistors from the selected byte are erased.

To program a memory cell, a programming control voltage V_{P} is applied to the control gate (word line) of the corresponding NVM transistor, and the bit line pair associated with the corresponding NVM transistor is grounded. All other bit line pairs (of columns not being programmed) are biased at a program counter-bias voltage V_{PC}. All select lines, the word lines in rows not being programmed, the ‘byte’ well regions, and the deep well region are grounded. Under these conditions, a tunnel current flows from the floating gate of the NVM transistor to be programmed to the corresponding channel region of the NVM transistor. Again, the programming current is composed of electrons (with negative charge) flowing in the opposite direction from transistor channel to the floating gate. Indeed, due to the strong positive gate bias a strong N-type channel is formed under gate, which is the source of tunneling electrons. Note that NVM transistors having bit lines coupled to receive the program counter-bias voltage V_{PC} are not programmed.

To read a memory cell, the associated select line is biased to the V_{DD} supply voltage, and the associated word line is biased to a read control voltage between 0 Volts and the V_{DD} supply voltage. A read control voltage is applied across the associated bit line pair, and a sense amplifier senses the resulting current. Although the read voltage can have either polarity, having positive bias on first metal bit line is more advantageous because of lower capacitance and higher speed.

Advantageously, the high erase and program control voltages V_{E} and V_{P} are not applied to the source/drain junctions of the memory transistors during erase and program operations of the present invention. Similarly, the high erase and program control voltages VE and VP are not applied across the gate dielectric structures of the access transistors. Consequently, the access transistors and the NVM transistors may be scaled to sub-0.35 micron processes.

The present invention will be more fully understood in view of the following description and drawings.

### BRIEF DESCRIPTION OF THE DRAWINGS

FIG. 1 is a circuit diagram illustrating a conventional memory system that includes an array of electrically erasable and programmable memory (EEPROM) cells.

FIG. 2 is a cross sectional view of one of the EEPROM cells of FIG. 1 and a pair of peripheral transistors, which are located on the same chip.

FIG. 3 is a circuit diagram of a memory array, which includes a plurality of EEPROM cells, in accordance with one embodiment of the present invention.

FIG. 4 is a cross sectional view of two of the EEPROM cells of FIG. 3 in accordance with one embodiment of the present invention.

FIG. 5 is a circuit diagram illustrating an erase operation being performed to two of the EEPROM cells of FIG. 3 in accordance with one embodiment of the present invention.

FIG. 6 is a circuit diagram illustrating a programming operation being performed to an EEPROM cell of FIG. 3 in accordance with one embodiment of the present invention.

FIG. 7 is a circuit diagram illustrating a read operation of two of the EEPROM cells of FIG. 3 in accordance with one embodiment of the present invention.

FIG. 8 is a circuit diagram of a 2×16 array of EEPROM cells in accordance with an alternate embodiment of the present invention.

FIG. 9 is a cross sectional view of a pair of EEPROM cells of the array of FIG. 8, in accordance with one embodiment of the present invention.

FIG. 10 is a cross sectional view of a pair of EEPROM cells of the array of FIG. 8, in accordance with another embodiment of the present invention.

FIG. 11 is a top view illustrating the layout of four EEPROM cells of the array of FIG. 8, in accordance with one embodiment of the present invention.

FIG. 12 is a table that illustrates bias voltages applied to the memory array of FIG. 8 to perform an erase operation in accordance with one embodiment of the present invention.

FIG. 13 is a table that illustrates bias voltages applied to the memory array of FIG. 8 to perform a program operation in accordance with one embodiment of the present invention.

FIG. 14 is a table that illustrates bias voltages applied to the memory array of FIG. 8 to perform a read operation in accordance with one embodiment of the present invention.

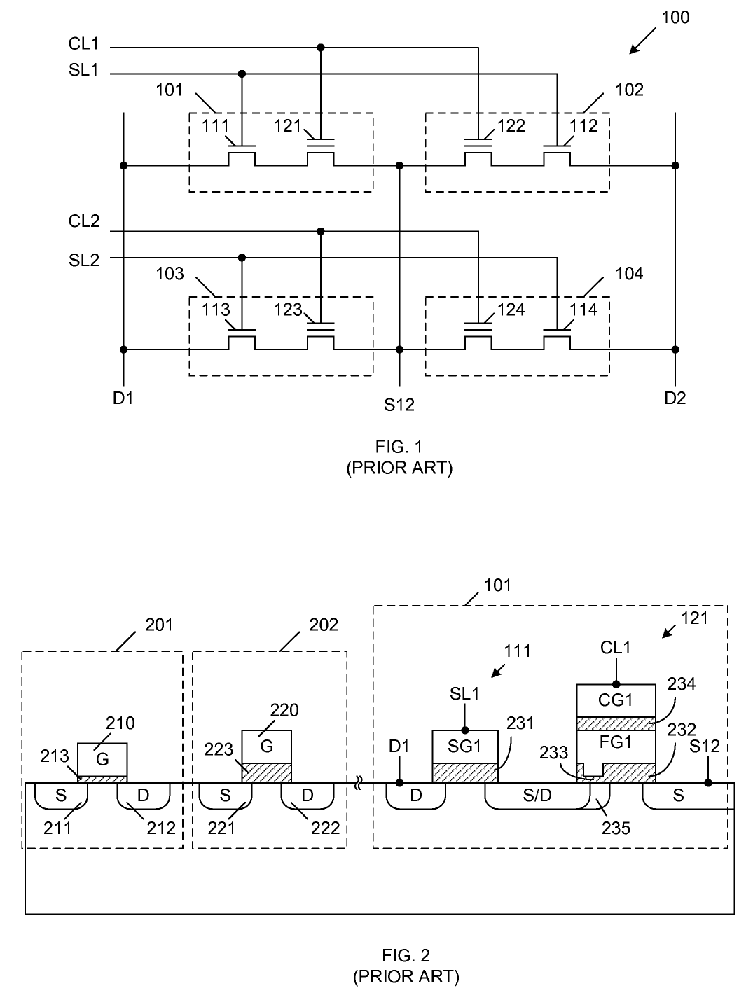

### DETAILED DESCRIPTION

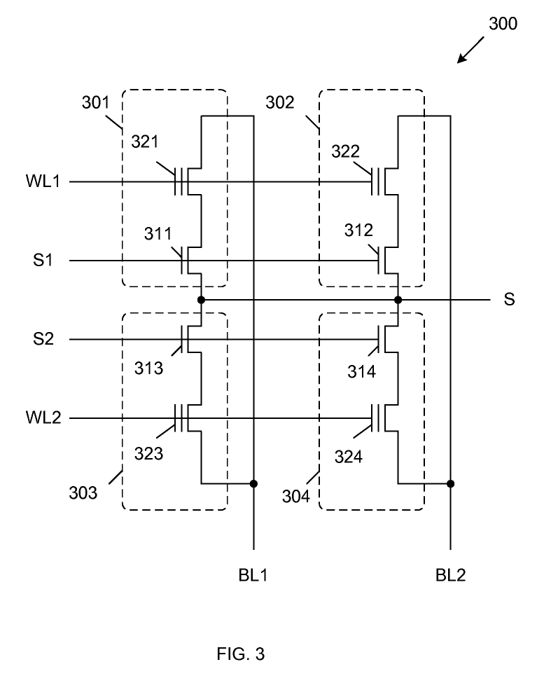

FIG. 3 is a circuit diagram of a 2×2 memory array 300, which includes EEPROM cells 301-304, in accordance with one embodiment of the present invention. Although a 2×2 memory array is described in the following embodiments, it is understood that this memory array can be easily expanded to implement larger arrays. In the described embodiments, EEPROM cells 301 and 302 are located in a first row of memory array 300, and EEPROM cells 303 and 304 are located in a second row of memory array 300. EEPROM cells 301 and 303 are located in a first column of memory array 300, and EEPROM cells 302 and 304 are located in a second column of memory array 300. Data words are written to (and read from) the various rows of memory array 300.

Each of the EEPROM cells 301-304 includes an access transistor 311-314, respectively, and an NVM transistor 321-324, respectively. The source of each access transistor 311-314 is commonly coupled to a source terminal S. The drains of access transistors 311-314 are coupled to the sources of NVM transistors 321-324, respectively. The drains of the NVM transistors in each column are commonly coupled to a corresponding bit line. Thus, the drains of NVM transistors 321 and 323 are coupled to bit line BL1, and the drains of NVM transistors 322 and 324 are coupled to bit line BL2.

The control gates of the NVM transistors in each row are commonly coupled to a corresponding word line. Thus, the control gates of NVM transistors 321 and 322 are coupled to word line WL1, and the control gates of NVM transistors 323 and 324 are coupled to word line WL2.

The select gates of the access transistors in each row are commonly coupled to a corresponding select line. Thus, the select gates of access transistors 301 and 302 are coupled to select line S1, and the select gates of access transistors 313 and 314 are coupled to select line S2.

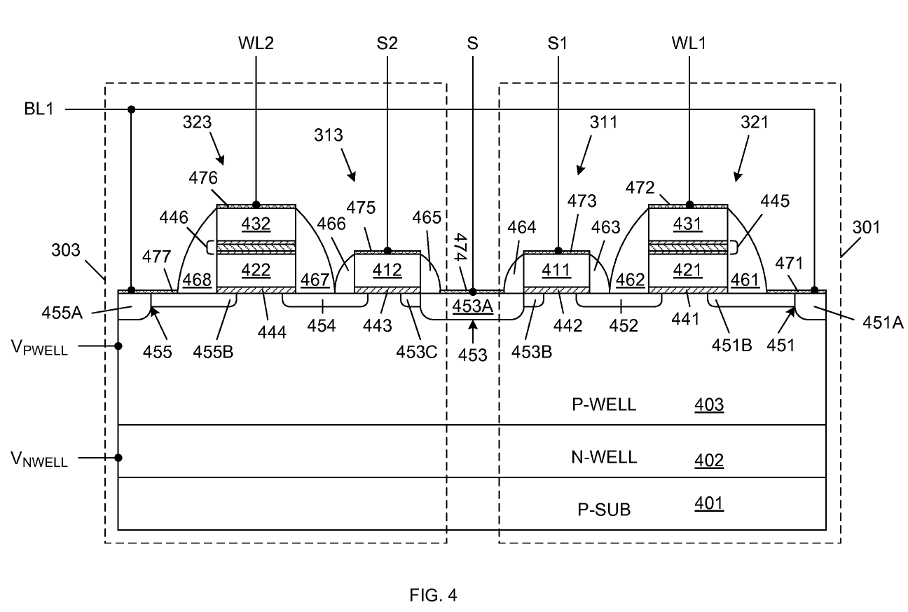

FIG. 4 is a cross sectional view of EEPROM cells 301 and 303 in accordance with one embodiment of the present invention. In the illustrated embodiment, EEPROM cells 301-304 are N-channel devices, which are fabricated in a P-well region 403. The P-well region 403 is contacted to receive a P-well bias voltage, V_{PWELL}. The P-well region 403, in turn, is fabricated in an N-well region 402. The N-well region 402 is contacted to receive an N-well bias voltage, V_{NWELL}. The N-well region 402, in turn is fabricated in a p-type semiconductor substrate 401.

NVM transistor 321 includes n-type drain region 451, n-type source/drain region 452, gate dielectric 441, floating gate 421, inter-gate dielectric 445, control gate 431 and dielectric sidewall spacers 461-462. Drain region 451 includes n+ contact region 451A and lightly doped (n−) drain region 451B. Drain region 451A is separated from the gate 421, thus preventing high field disturb during programming. Salicide regions 471 and 472 are formed on the upper surfaces of drain contact region 451A and control gate 431. In the described embodiment, inter-gate dielectric 445 is a stacked oxide-nitride-oxide (ONO) structure.

Access transistor 311 includes n-type source/drain region 452 (which is shared with NVM transistor 321), source region 453, gate dielectric 442, control gate 411 and dielectric sidewall spacers 463-464. Source region 453 includes n+ contact region 453A and lightly doped (n−) regions 453B-453C. Salicide regions 473 and 474 are formed on the upper surfaces of control gate 411 and source contact region 453A.

Access transistor 313 includes n-type source region 453 (which is shared with access transistor 311), n-type source/drain region 454, gate dielectric 443, control gate 412 and dielectric sidewall spacers 465-466. Salicide region 475 is formed on the upper surface of control gate 412.

NVM transistor 323 includes n-type drain region 455, n-type source/drain region 454, gate dielectric 444, floating gate 422, inter-gate dielectric 446, control gate 432 and dielectric sidewall spacers 467-468. Drain region 455 includes n+ contact region 455A and lightly doped (n−) drain region 455B. Salicide layers 476 and 477 are formed on the upper surfaces of control gate 432 and drain contact region 455A. In the described embodiment, inter-gate dielectric 446 is a stacked oxide-nitride-oxide (ONO) structure.

Although not illustrated in FIG. 4, EEPROM cells 302 and 304 have the same construction as EEPROM cells 301 and 303. Memory array 300 operates as follows in accordance with one embodiment of the present invention.

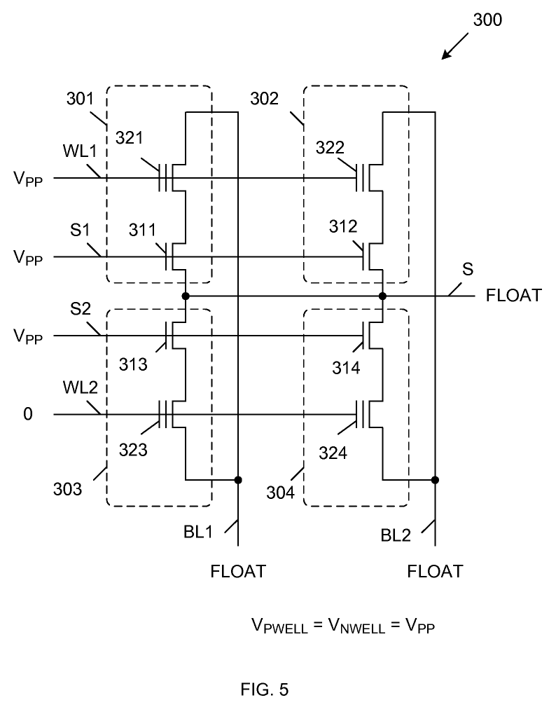

FIG. 5 is a circuit diagram illustrating an erase operation being performed to EEPROM cells 303 and 304 of memory array 300. During this erase operation, common source region S and bit lines BL1-BL2 are maintained in a floating state (i.e., not connected to any external voltage). Word line WL1, select lines S1-S2, P-well region 403 and N-well region 402 are coupled to receive a high programming voltage V_{PP}, on the order of about 15 Volts. That is, V_{PWELL} and V_{NWELL} are set equal to V_{PP}. Word line WL2, which connects to the NVM transistors 323-324 selected for erase, is coupled to the ground voltage supply terminal.

Under these conditions, a large voltage (V_{PP}) exists between the P-well region 403 and the control gate 432 of NVM transistor 323. As a result, a Fowler-Nordheim tunneling current is introduced between P-well region 403 and floating gate 422, which is coupled to the high voltage on the control gate 432 of NVM transistor 323, such that excess electrons are removed from floating gate 422. At the end of the erase operation, NVM transistor 323 exhibits a relatively low threshold voltage. Because NVM transistor 324 is biased in the same manner as NVM transistor 323, NVM transistor 324 is also erased. Note that all NVM transistors in the same row will be simultaneously erased.

In the described example, NVM transistors 321 and 322 are not erased because word line WL1 is held at the high voltage V_{PP}. In an alternate example, NVM transistors 321 and 322 can be erased at the same time as NVM transistors 323 and 324 by coupling word line WL1 to the ground voltage supply terminal (rather than the V_{PP} programming voltage terminal).

Note that all drain and source diffusions will acquire a potential close to the voltage of P-well 403, so that the junction bias′ associated with these diffusions is close to zero. Also, the high programming voltage V_{PP} is not applied between any terminals of the access transistors 311-314 during the erase operation.

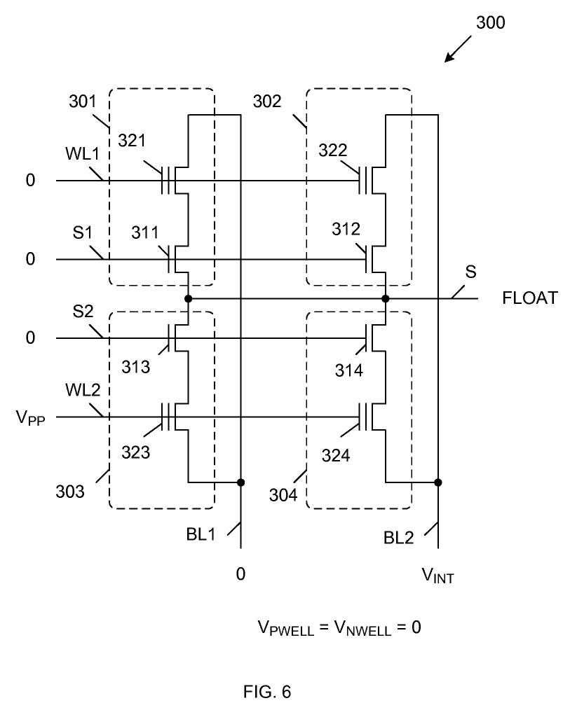

FIG. 6 is a circuit diagram illustrating a programming operation being performed to EEPROM cell 303 of memory array 300. During this programming operation, common source region S is maintained in a floating state. Word line WL2 is coupled to receive the high programming voltage V_{PP}. Select lines S1-S2, word line WL1, bit line BL1, P-well region 403 and N-well region 402 are coupled to the ground voltage supply terminal. Bit line BL2 is coupled to receive an intermediate voltage V_{INT}, on the order of about 5 Volts.

Under these conditions, a large voltage (a large fraction of V_{PP}) exists between the channel region below gate dielectric 444 (which has the same potential as drain region 455) and the floating gate 422 of NVM transistor 323. As a result, a Fowler-Nordheim tunneling current flows between drain region 455 and floating gate 422 of NVM transistor 323, such that electrons are trapped on floating gate 422. At the end of the programming operation, NVM transistor 323 exhibits a relatively high threshold voltage. Because the drain of NVM transistor 324 is biased with the intermediate voltage V_{INT}, the voltage across the gate dielectric located between the drain and the floating gate of NVM transistor 324 is not high enough to induce a Fowler-Nordheim tunneling current. Consequently, NVM transistor 324 is not programmed. However, note that NVM transistor 324 could be programmed at the same time as NVM transistor 323 by connecting bit line BL2 to the ground voltage supply terminal.

In the described example, NVM transistors 321 and 322 are not disturbed because bit line potential is too low for Fowler-Nordheim tunneling. Moreover, there is no drain current through NVM transistors 321 and 322 because the word line WL1 and the select line S1 are held at the ground supply voltage. In an alternate example, NVM transistor 321 can be programmed at the same time as NVM transistor 323 by coupling word line WL1 to receive the high voltage V_{PP}.

Note that the high programming voltage V_{PP} is not applied to the access transistors 311-314 during the programming operation.

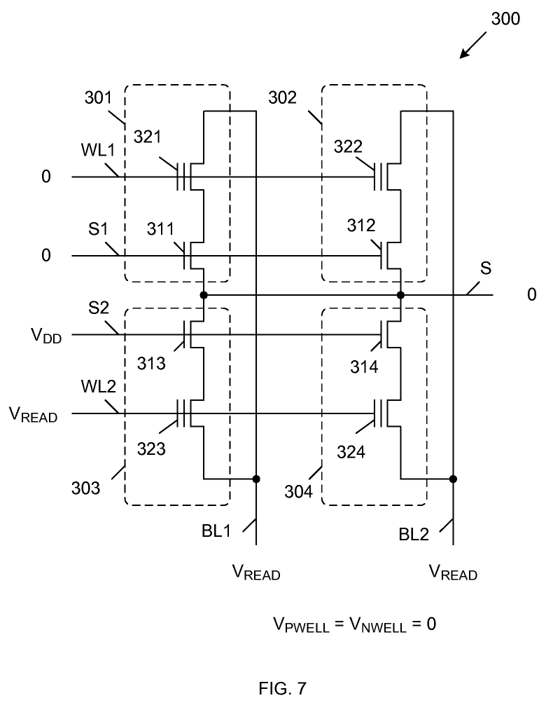

FIG. 7 is a circuit diagram illustrating a read operation that accesses EEPROM cells 303 and 304 of memory array 300. During this read operation, common source region S, word line WL1 and select line S1 are coupled to the ground voltage supply terminal. As a result, access transistors 311-312 and NVM transistors 321-322 are turned off. Select line S2 is coupled to receive the V_{DD} supply voltage. As a result, access transistors 313 and 314 are turned on. Word line WL2 is coupled to receive the read voltage V_{READ}. The read voltage V_{READ} is selected to have a value that is large enough to turn on a corresponding NVM transistor that is in the erased state (i.e., in a low threshold voltage state). The read voltage V_{READ} is selected to be smaller than the minimum value which turns on a corresponding NVM transistor that is in the programmed state (i.e., in a high threshold voltage state). In the described example, the read voltage V_{READ} is 2 Volts, but other values can be used in the range of 1 to 5 Volts.

Bit lines BL1 and BL2 are coupled to receive the read voltage V_{READ}, or a value close to V_{READ} in the same range of 1 to 5V. Sense amplifier circuits (not shown) are also coupled to bit lines BL1 and BL2. These sense amplifiers latch a read data value having a first state if the current flowing on the corresponding bit line exceeds a threshold current value (i.e., if the corresponding NVM transistor is in an erased state). Conversely, these sense amplifiers latch a read data value having a second state if the current flowing on the corresponding bit line is less than the threshold current value (i.e., if the corresponding NVM transistor is in a programmed state).

Note that the high programming voltage V_{PP} is not applied to any transistors during the read operation. Because the high programming voltage V_{PP} is not applied to the drains, sources or select gates of access transistors 311-314 during the erase, program or read operations, these access transistors do not require thick gate oxide and do not require large spacing at diffusion contacts. As a result, memory array 300 can advantageously be scaled to sub-0.35 micron processes.

The present invention also includes a process for fabricating the memory array 300 and the associated peripheral devices. In accordance with one embodiment, this process is implemented as follows. A pad oxide layer is formed over a p-type monocrystalline silicon wafer having a <100> crystalline structure. An N-well region mask is formed over the wafer. N-well implants are then performed through the N-well mask, and the N-well mask is removed. The N-well implant is diffused at a depth of 3-5 microns in a high temperature furnace. After removing the N-well oxide, a pad oxide layer and an overlying silicon nitride (Si₃N₄) layer are then formed over the wafer surface. An active region mask, which defines the locations of the active regions to be formed on the wafer, is then formed over the resulting structure. An etch is performed through the active region mask, thereby exposing the inactive regions of the wafer. The active region mask is then removed. Field oxide is then thermally grown in the inactive regions, to a thickness of about 500 nm. The pad oxide layer and silicon nitride layer are then removed, and a sacrificial oxide layer, having a thickness of about 30 nm, is formed over the upper surface of the wafer.

A p-well mask, which defines the locations of P-well regions (e.g., P-well region 403) to be formed in the wafer, is then formed over the resulting structure. P-well implants are then performed through the P-well mask, and the P-well mask is removed. The sacrificial oxide layer is then removed (e.g., by etching).

A high voltage gate dielectric layer is then formed, in two steps, over the resulting structure. The high voltage gate dielectric layer can be, for example, thermally grown silicon oxide having a thickness of about 30 nm. In the described embodiments, the high voltage gate dielectric layer is used to form peripheral transistors that route the V_{PP} programming voltage (15 Volts) to word lines WL1 and WL2. In the first step, a thinner oxide is grown, for example, to a thickness of about 25 nm. An intermediate voltage oxide mask is formed over the structure and the first step oxide is etched. The low voltage oxide mask is then removed. An intermediate voltage gate dielectric layer is then grown over the resulting structure, such that the intermediate voltage areas have an oxide of about 10 nm, while the remaining high voltage area has an oxide of about 30 nm. In the described embodiments, the intermediate voltage gate dielectric layer is used in transistors that operate in response to the intermediate voltage of 5 Volts. For example, the intermediate voltage gate dielectric layer is used to form gate dielectric layers 442 and 443 of access transistors 311 and 313, respectively, and gate dielectric layers 441 and 444 of NVM transistors 321 and 323, respectively. The intermediate voltage gate dielectric layer is also used to form similar structures in access transistors 312 and 314 and NVM transistors 322 and 324. The intermediate voltage gate dielectric layer is also used to form peripheral devices (e.g., transistors) which operate in response to an intermediate voltage.

A first layer of polycrystalline silicon (polysilicon) having a thickness of 100-200 nm is then deposited over the gate dielectric layer. The first polysilicon layer is doped with a n-type impurity (N+), such that the first polysilicon layer becomes conductive. A silicon oxide-silicon nitride-silicon oxide (ONO) structure is then formed over the first polysilicon layer. This ONO structure is used in NVM transistors 321-324 (see, e.g., ONO structures 445-446).

A first gate mask, which defines the locations of the floating gates of NVM transistors 321-324 and of high-voltage peripheral transistors is then formed over the second dielectric layer. A dry etch is performed through the ONO dielectric and the first polysilicon layer and, thereby forming the control gates. The first gate mask is then removed.

A low voltage oxide mask is then formed over the resulting structure. A threshold adjustment is performed for the low voltage transistors and the intermediate oxide is etched. The low voltage oxide mask is then removed. A low voltage gate dielectric layer is then formed over the resulting structure. The low voltage gate dielectric layer can be, for example, thermally grown silicon oxide having a thickness of about 7 nm. In the described embodiments, the low voltage gate dielectric layer is used to form peripheral transistors that control the addressing of memory array 300 and all logic functions.

A second layer of polysilicon having a thickness of 200-300 nm is then deposited over the ONO layer. The second polysilicon layer is doped with an n-type impurity (N+), such that the second polysilicon layer becomes conductive.

A second gate mask, which defines the locations of the low-voltage peripheral transistors, is then formed over the second layer of polysilicon. A dry etch is performed through the second polysilicon layer, thereby forming the gates of the low-voltage peripheral transistors. The second gate mask is then removed.

A high voltage n-type lightly doped drain (HVNLDD) mask, which defines the locations of the lightly doped n-type regions in memory array 300 (e.g., 451B 452, 453B, 453C, 454 and 455B) and the lightly doped n-type regions in the high voltage n-channel peripheral transistors. An n-type LDD implant is performed through the HVNLDD mask, thereby forming the lightly doped drain regions of the high-voltage NMOS transistors. The HVNLDD mask is then removed.

A low voltage n-type lightly doped drain (NLDD) mask, which defines the locations of the lightly doped n-type regions the low voltage n-channel peripheral transistors. An n-type LDD implant is performed through the NLDD mask, thereby forming the lightly doped drain regions of the low-voltage peripheral NMOS transistors. The NLDD mask is then removed.

A p-type lightly doped drain (PLDD) mask, which defines the locations of the lightly doped p-type regions of the p-channel peripheral transistors. A p-type LDD implant is performed through the PLDD mask, thereby forming the lightly doped drain regions of the p-channel peripheral transistors. The PLDD mask is then removed.

A sidewall dielectric layer is then deposited over the resulting structure. The sidewall dielectric layer is then etched, thereby forming dielectric sidewall spacers (e.g., sidewall spacers 461-468) adjacent to the various polysilicon structures.

A n-type source/drain mask, which defines the locations of the n-type source and drain contact regions (e.g., regions 451A, 453A and 455A) is formed over the resulting structure. A n+ implant is performed through the n-type source/drain mask, thereby forming the n-type source/drain contact regions of the NMOS transistors. The n-type source/drain mask is then removed.

A p-type source/drain mask, which defines the locations of the p-type source and drain contact regions is formed over the resulting structure. A p+ implant is performed through the p-type source/drain mask, thereby forming the required p-type source/drain contact regions of the PMOS transistors. The p-type source/drain mask is then removed.

A salicide mask, which defines the locations where salicide should not be formed, is formed over the resulting structure. A layer of metal silicide is then deposited over the resulting structure. An anneal step is then performed, thereby causing the metal silicide layer to react with underlying silicon regions, thereby forming self-aligned polysilicide (salicide). The unreacted portions of the metal silicide layer are then removed. The salicide mask is then removed. The back end processing is then performed, wherein: pad oxide/oxide is deposited over the resulting structure; BPSG deposition/flow is performed over the pad oxide/oxide; contact openings are formed through the pad oxide/oxide/BPSG; the contact openings are filled with conductive plugs; a first metal layer is deposited over the resulting structure and patterned; an inter-metal oxide layer is formed over the resulting structure; the inter-metal oxide is planarized by chemical mechanical polishing (CMP); vias are formed in the inter-metal oxide; the vias are filled by conductive plugs; a second metal layer is deposited and patterned; a bake is performed in the presence of hydrogen; and a passivation layer is deposited and patterned to expose the pads on the wafer.

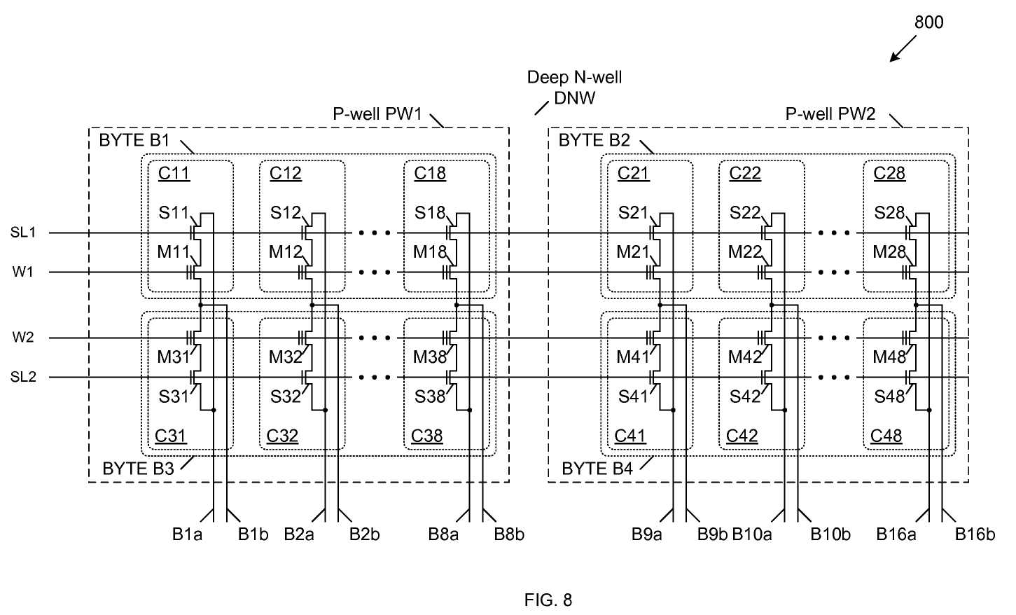

FIG. 8 is a circuit diagram of a 2×16 memory array 800, which includes EEPROM cells C11-C18, C21-C28, C31-C38 and C41-C48, in accordance with an alternate embodiment of the present invention. Although a 2×16 memory array is described in the following embodiments, it is understood that this memory array can be easily expanded to implement larger arrays. In the described embodiments, EEPROM cells C11-C18 and C21-C28 are located in a first row of memory array 800, and EEPROM cells C31-C38 and C41-C48 are located in a second row of memory array 800. In general, the EEPROM cells of memory array 800 are labeled C_{xy}, wherein X identifies a data byte, and Y identifies a bit within the data byte. Thus, EEPROM cells C11-C18 store 8-bits of data byte B1, EEPROM cells C21-C28 store 8-bits of data byte B2, EEPROM cells C31-C38 store 8-bits of data byte B3, and EEPROM cells C41-C48 store 8-bits of data byte B4.

Each of the 16 columns of EEPROM cells includes a corresponding bit line pair. Thus, column N includes bit line pair BNa-BNb, where N includes the integers from 1 to 16. Within memory array 800, EEPROM cells are grouped in pairs in the column direction. For example, EEPROM cell C11 is grouped with EEPROM cell C31 in the first column of memory array 800. This grouping exists because EEPROM cell C11 shares a common source diffusion region with EEPROM cell C31. In a particular embodiment, memory array 800 can be expanded to include an even number of rows, by adding pairs of rows identical to the first two rows illustrated in FIG. 8.

In accordance with one embodiment of the present invention, the EEPROM cells of all bytes sharing the same bit line pairs are fabricated in a corresponding well region. Thus, the EEPROM cells that store bytes B1 and B3 are fabricated in a first p-well region PW1, and the EEPROM cells that store bytes B2 and B4 are fabricated in a second p-well region PW2. The EEPROM cells C11-C18 and C31-C38 fabricated in p-well region PW1 form a first sub-array of memory array 800, which includes the first eight columns of memory array 800. Similarly, the EEPROM cells C21-C28 and C41-C48 fabricated in p-well region PW2 form a second sub-array of memory array 800, which includes the next eight columns of memory array 800. Because the each of the p-well regions PW1 and PW2 is assigned to a different set of bytes, these p-well regions may be referred to as ‘byte’ well regions.

P-well regions PW1 and PW2 are electrically isolated from one another. In one embodiment, the separate p-well regions PW1 and PW2 are formed in a deep n-well region DNW, which isolates the p-well regions PW1 and PW2 for low voltage differences of less than about 5 Volts. The deep n-well region DNW may be formed in a p-type semiconductor substrate. Note that the polarities of the above-described regions assume that the EEPROM cells are fabricated from n-channel devices. The polarities may be reversed if the EEPROM cells are fabricated with p-channel devices.

Each of the EEPROM cells C_{xy} includes a corresponding access transistor S_{xy} and a corresponding NVM transistor M_{xy}. The drain of each access transistor C_{xy} is coupled to a bit line of the associated column. The source of each access transistor C_{xy} is coupled to the drain of the corresponding NVM transistor M_{xy}. The source of each NVM transistor M_{xy} is coupled to the other (complementary) bit line of the associated column. For example, the drains of access transistors S11 and S31 are coupled to bit line B1a, and the sources of NVM transistors M11 and M31 are coupled to bit line B1b.

The control gates of the NVM transistors in each row are commonly coupled to a corresponding word line. Thus, the control gates of NVM transistors M₁₁-M₁₈ and M₂₁-M₂₈ are coupled to word line W1, and the control gates of NVM transistors M₃₁-M₃₈ and M₄₁-M₄₈ are coupled to word line W2. The select gates of the access transistors in each row are commonly coupled to a corresponding select line. Thus, the select gates of access transistors S₁₁-S₁₈ and S₂₁-S₂₈ are coupled to select line SL1, and the select gates of access transistors S₃ₗ-S₃₈ and S₄₁-S₄₈ are coupled to select line SL2.

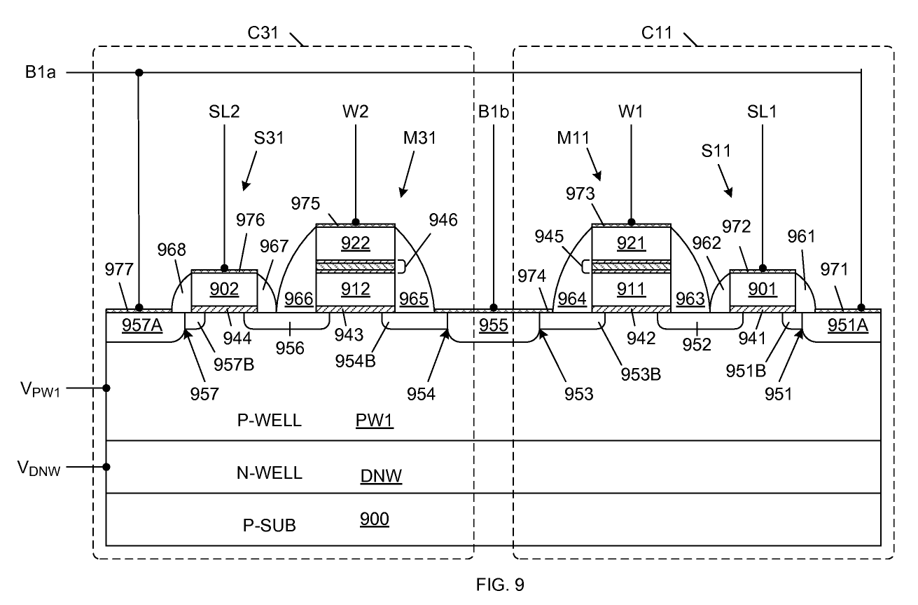

FIG. 9 is a cross sectional view of EEPROM cells C11 and C31 of FIG. 8 in accordance with one embodiment of the present invention. Other pairs of EEPROM cells that share a common source region (e.g., EEPROM cells C22 and C42) have the same structure as EEPROM cells C11 and C31.

In the illustrated embodiment, EEPROM cells C11 and C31 are N-channel devices, which are fabricated in P-well region PW1. The P-well region PW1 is contacted to receive a P-well bias voltage, V_{PW1}. The P-well region PW1, in turn, is fabricated in an N-well region DNW. The N-well region DNW is contacted to receive an N-well bias voltage, V_{DNW}. The N-well region DNW, in turn is fabricated in a p-type semiconductor substrate 900 (which is grounded).

Access transistor S11 includes n-type drain region 951, n-type source region 952, gate dielectric 941, control gate 901 and dielectric sidewall spacers 961 and 962. Drain region 951 includes n+ contact region 951A and lightly doped (n−) drain region 951B. Salicide regions 971 and 972 are formed on the upper surfaces of drain contact region 951A and control gate 901, respectively.

NVM transistor M11 includes n-type drain region 952 (which is shared with access transistor S11), n-type source region 953, tunnel gate dielectric 942, floating gate 911, inter-gate dielectric 945, control gate 921 and dielectric sidewall spacers 963-964. Source region 953 includes n+ source contact region 955 and lightly doped (n−) source region 953B. Source contact region 955 is separated from the gate 911, thus preventing high field disturb during programming. Salicide regions 973 and 974 are formed on the upper surfaces of control gate 921 and source contact region 955, respectively.

Access transistor S31 includes n-type drain region 957, n-type source region 956, gate dielectric 944, control gate 902 and dielectric sidewall spacers 967 and 968. Drain region 957 includes n+ contact region 957A and lightly doped (n−) drain region 957B. Salicide regions 977 and 976 are formed on the upper surfaces of drain contact region 956A and control gate 902, respectively. NVM transistor M31 includes n-type drain region 956 (which is shared with access transistor S31), n-type source region 954, tunnel gate dielectric 943, floating gate 912, inter-gate dielectric 946, control gate 922 and dielectric sidewall spacers 965-966. Source region 954 includes n+ source contact region 955 (which is shared with NVM transistor M11) and lightly doped (n−) source region 954B. Source contact region 955 is separated from the gate 912, thus preventing high field disturb during programming. Salicide region 975 is formed on the upper surface of control gate 922.

In accordance with on embodiment of the present invention, the gate dielectric layers 941 and 944 of access transistors S11 and S31 have a first effective oxide thickness, and the tunnel gate dielectric layers 942 and 943 of NVM transistors M11 and M31 have a second effective oxide thickness, wherein the first and second effective oxide thicknesses are different. For example, gate dielectric layers 941 and 944 of select transistors S11 and S31 may be formed from a common thermally grown silicon oxide layer, which has a thickness of about 120 Angstroms, and tunnel gate dielectric layers 942 and 943 of NVM transistors M11 and M31 may be formed from the a common thermally grown silicon oxide layer having a thickness of about 90 Angstroms. In this embodiment, floating gate electrodes 911-912 are formed from a first polysilicon layer, and control gate electrodes 901-902 and 921-922 are formed from a second (subsequently deposited) polysilicon layer. Note that inter-gate dielectric structures 945 and 946, which may be stacked oxide-nitride-oxide (ONO) structures, are formed between the first and second polysilicon layers.

In an alternate embodiment of the present invention, gate dielectric layers 941 and 944 of access transistors S11 and S31, and the tunnel gate dielectric layers 942 and 943 of NVM transistors M11 and M31 are made from the same dielectric layer, and have the same effective oxide thickness. For example, gate dielectric layers 941, 924, 943 and 944 may be formed from a common thermally grown silicon oxide layer, which has a thickness of about 90 Angstroms. In this embodiment, control gate electrodes 901-902 and floating gate electrodes 911-912 are formed from the same polysilicon layer.

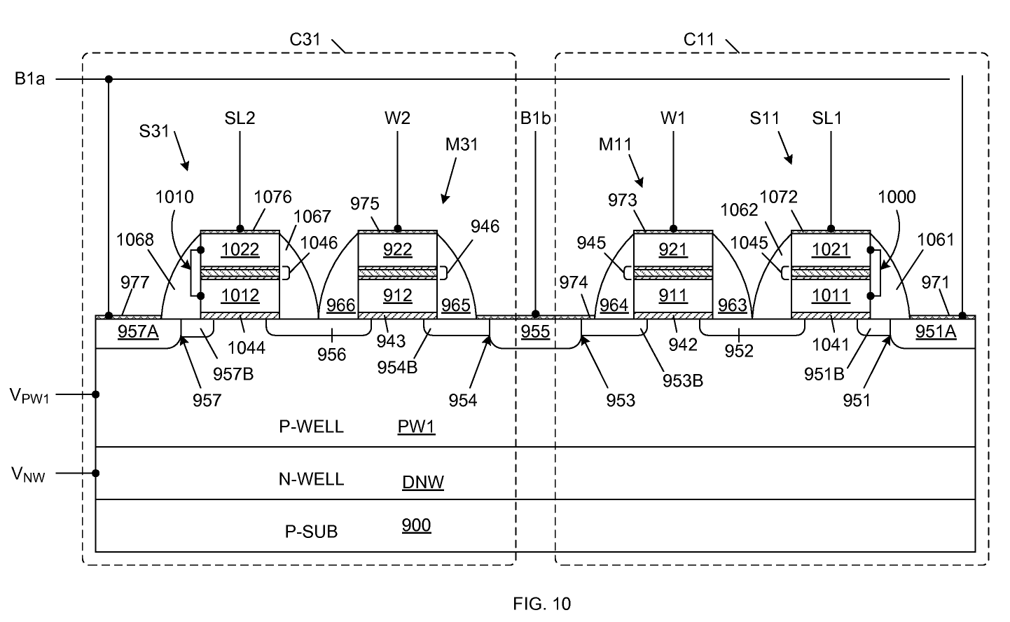

FIG. 10 is a cross sectional view of EEPROM cells C11 and C31 in accordance with an alternate embodiment of the present invention. Similar elements are labeled with similar reference numbers in FIGS. 9 and 10. NVM transistors M11 and M31 are substantially identical in FIGS. 9 and 10. However, in the embodiment of FIG. 10, access transistors S11 and S31 are modified to have a structure similar to NVM transistors M11 and M31. More specifically, access transistor S11 is modified to include gate dielectric 1041, ‘floating’ gate 1011, inter-gate dielectric structure 1045, control gate 1021, dielectric sidewall spacers 1061-1062, salicide region 1072 and gate connection 1000. Similarly, access transistor S31 is modified to include gate dielectric 1044, ‘floating’ gate 1012, inter-gate dielectric structure 1046, control gate 1022, dielectric sidewall spacers 1067-1068, salicide region 1076 and gate connection 1010.

In the embodiment illustrated by FIG. 10, access transistors S11 and S31 are fabricated from the same layers as NVM transistors M11 and M12, thereby simplifying the fabrication of EEPROM cells C11 and C12. Thus, gate dielectric structures 942, 943, 1041 and 1044 are fabricated at the same time, from the same dielectric layer. In one embodiment, gate dielectric structures 942, 943, 1041 and 1042 are formed from the same thermally grown silicon oxide layer having a thickness of about 90 Angstroms. Similarly, floating gate structures 911, 912, 1011 and 1012 are fabricated at the same time from a first polysilicon layer. Inter-gate dielectric structures 945, 946, 1045 and 1046 are fabricated at the same time from the same dielectric (ONO) layers. Control gate structures 921, 922, 1021 and 1022 are also fabricated at the same time from a second polysilicon layer. As a result, the fabrication process for the memory array 800 is simplified.

Gate connection 1000 forms an electrical connection between ‘floating’ gate 1011 and control gate 1021 at a location outside of the cross sectional view of FIG. 10. Similarly, gate connection 1010 forms an electrical connection between ‘floating’ gate 1012 and control gate 1022 at a location outside of the cross sectional view of FIG. 10. Gate connections 1000 and 1010 can be made, for example by a contact or via plug. Because gate connections 1000 and 1010 electrically connect ‘floating’ gates 1011 and 1012 to control gates 1021 and 1022, respectively, these ‘floating’ gates 1011 and 1012 do not actually float, but are biased by the access control signals provided on select lines SL1 and SL2, respectively.

In one variation of the embodiment of FIG. 10, gate connections 1000 and 1010 are omitted, such that gates 1011 and 1012 are, in fact, ‘floating’ gate electrodes. In this variation, charge is initially removed from these floating gate electrodes 1011 and 1012 (e.g., by exposure to ultra-violet light). After these floating gate electrodes 1011 and 1012 have been initialized in this manner, these floating gate electrodes 1011 and 1012 are not subjected to program or erase conditions (described below), such that the floating gate electrodes 1011 and 1012 maintain the initialized states. In this variation, the voltages applied to select lines SL1 and SL2 may need to be increased with respect to the voltages applied select lines SL1 and SL2 when gate connections 1000 and 1010 are present, in order to provide the same resulting voltages on floating gate electrodes 1011 and 1012. For example, if the V_{DD} supply voltage is applied to select line SL1 to perform a read operation to memory cell C11 when gate connection 1000 is present, then a voltage greater than the V_{DD} supply voltage must be applied to select line SL1 to provide the same voltage on floating gate 1011 when gate connection 1000 is not present.

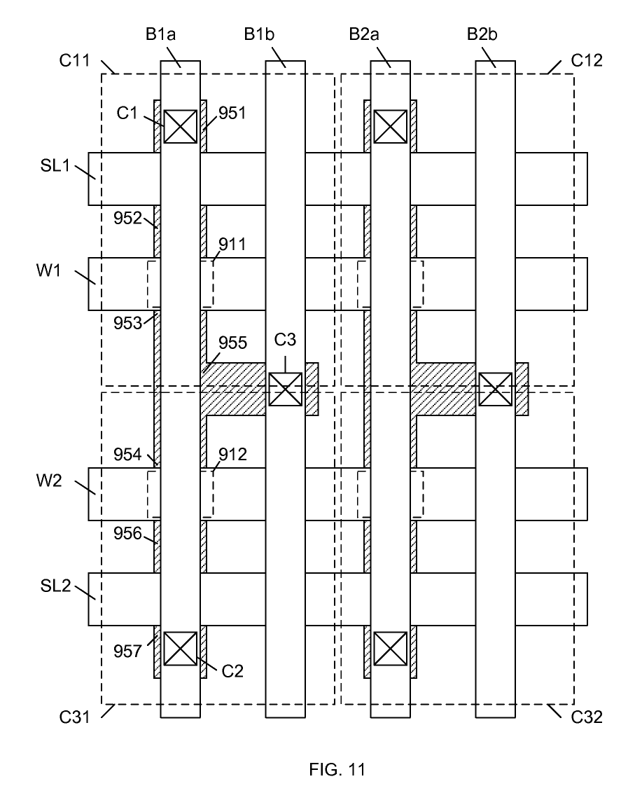

FIG. 11 is a top view of the layout of EEPROM cells C11-C12 and C31-C32 in accordance with one embodiment of the present invention. All of the EEPROM cells of memory array 800 can be laid out in the same manner as EEPROM cells C11-C12 and C31-C32. In the layout of FIG. 11, the n-type source/drain diffusion regions of EEPROM cells C11-C12 and C31-C32 are shown as shaded regions. For example, FIG. 11 illustrates n-type source/drain diffusion regions 951-957 of EEPROM cells C11-C12. Polysilicon select lines SL1-SL2 and polysilicon word lines W1-W2 extend in parallel along a first axis, as illustrated. The floating gates of NVM transistors M11-M12 and M31-M32 are shown in dashed lines. For example, FIG. 11 illustrates the floating gates 911 and 912 of NVM transistors M11 and M12, respectively. (Note that the floating gates 1011 and 1012 of the embodiment of FIG. 10 would be located at similar locations under select lines SL1 and SL2.) Metal bit lines B1a-B1b and B2a-B2b extend over the above-described structures. These bit lines extend in parallel along a second axis, which is perpendicular to the first axis (of the select lines and word lines). Bit line contacts, which are illustrated as squares containing X's in FIG. 11, provide electrical connections between the bit lines and underlying source/drain diffusion regions. For example, FIG. 11 illustrates bit line contacts C1 and C2, which connect the drain regions 951 and 957 of access transistors S11 and S31 to bit line B1a; and bit line contact C3, which connects the shared source region 955 of NVM transistors M11 and M31 to bit line B1b. Note that the transistors of EEPROM cells C11 and C31 extend substantially along a linear region that exists below bit line B1a, wherein the shared source region 955 extends perpendicularly away from this linear region to allow for the connection of complementary bit line B1b. This configuration allows the EEPROM cells of memory array 800 to be laid out in an area efficient manner. Note that the bit lines B1a-B1b and B2a-B2b can be formed from the same metal layer (e.g., metal-1). Alternately, bit lines B1a and B2a can be formed from one metal layer (e.g., metal-1), and bit lines B1b and B2b can be formed from another metal layer (e.g., metal-2).

The operation of memory array 800 will now be described. Memory array 800 operates as follows in accordance with one embodiment of the present invention.

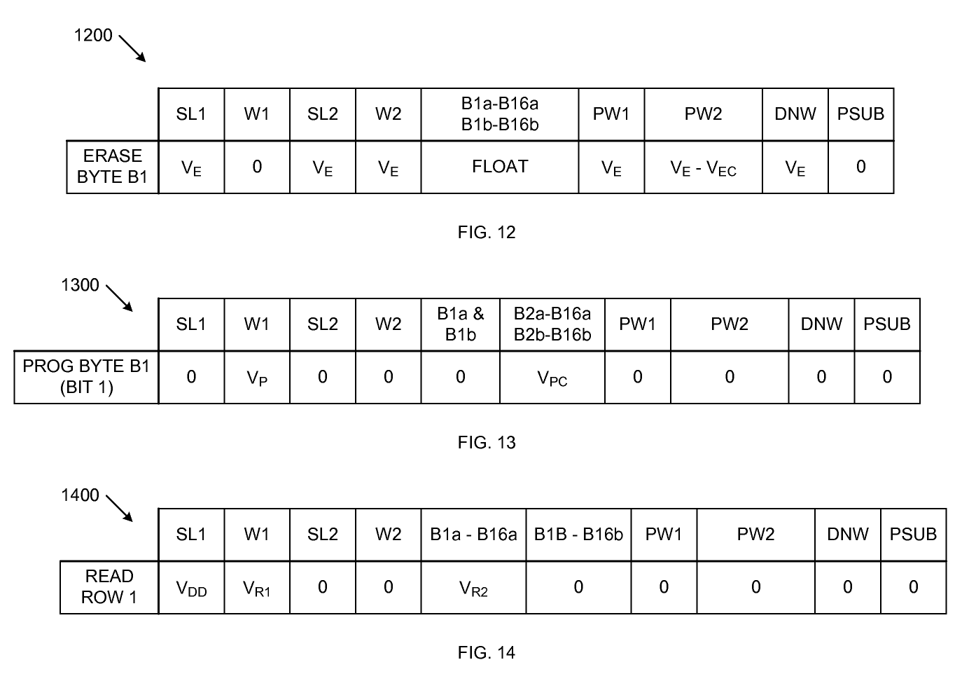

FIG. 12 is a table 1200 that illustrates the voltages applied to memory array 800 to perform an erase operation to byte B1 in accordance with one embodiment of the present invention. Note that erase operations can be performed on a per byte basis. Other bytes of memory array 800 can be erased in the same manner as byte B1.

Word line W1 and the p-type substrate 900 are grounded (0 Volts), and a positive boosted erase voltage V_{E} is applied to select lines SL1-SL2, word line W2, p-well region PW1, and deep n-well region DNW. All bit lines are left in a floating state, and the second p-well region PW2 is biased with a voltage equal to the positive boosted erase voltage V_{E} minus an erase counter-bias voltage V_{EC}. The voltages V_{E} and V_{EC} are selected in view of the thickness of the tunnel oxide of the NVM transistors to meet the operating characteristics described below.

Each NVM transistor M11-M18 of byte B1 has a control gate biased to 0 Volts and a corresponding P-well region PW1 biased to the full erase voltage V_{E}. The net voltage of V_{E} applied across NVM transistors M11-M18 is sufficient to cause electrons to tunnel from the floating gates of these NVM transistors M11-M18 to p-well region PW1, thereby erasing EEPROM cells C11-C18 (i.e., lowering the threshold voltages of NVM transistors M11-M18). In one embodiment, the erase voltage V_{E} is selected to have a value of about 15 Volts.

Under the bias conditions defined by table 1200, each of the NVM transistors M21-M28 of byte B2 has a control gate biased to 0 Volts and is located in a corresponding p-well region PW2 that is biased to a voltage equal to V_{E}-V_{EC}. As a result, the net voltage applied across NVM transistors M21-M28 is equal to V_{E}-V_{EC}, which is less than the net voltage (V_{E}) applied across NVM transistors M11-M18. As a result of the reduced net voltage applied across NVM transistors M21-M28, the states of these NVM transistors M21-M28 are not disturbed during the erase operation of byte B1. That is, the net voltage (V_{E}-V_{EC}) applied across NVM transistors M21-M28 is not large enough to result in substantial tunneling of electrons from the floating gates of NVM transistors M21-M28 to p-well region PW2. In one embodiment, the voltage V_{EC} is selected to have a voltage of about 4 to 6 Volts, such that the net voltage V_{E}-V_{EC} is approximately equal to 9 to 11 Volts.

Note that each NVM transistor M31-M38 of byte B3 has a control gate biased to the boosted erase voltage V_{E}, and a corresponding P-well region PW1 also biased to the boosted erase voltage V_{E}. Under these conditions, the states of NVM transistors M31-M38 are not disturbed, because there is no net voltage difference developed across these NVM transistors.

Each NVM transistor M41-M48 of byte B4 has a control gate biased to the boosted erase voltage V_{E}, and a corresponding P-well region PW2 biased to a voltage equal to V_{E}-V_{EC}. As a result, the net voltage applied across NVM transistors M41-M48 is equal to V_{EC}, which is less than the net voltage applied across either NVM transistors M11-M18 or NVM transistors M21-M28. Consequently, the states of NVM transistors M41-M48 are not disturbed during the erase operation of byte B1.

FIG. 13 is a table 1300 that illustrates the voltages applied to memory array 800 to perform a program operation to bit 1 of byte B1 in accordance with one embodiment of the present invention. Note that program operations are performed on a per bit basis (wherein any combination of the bits of a byte may be programmed during a program operation). As will become apparent in view of the following description, other bits of byte B1 can be programmed at the same time as bit 1 by grounding the bit lines associated with these other bits. For example, bit 2 (of byte B1) can be programmed at the same time as bit 1 (of byte B1) by grounding bit lines B2a and B2b.

To program bit 1 of byte B1, select lines SL1-SL2, word line W1, bit line pair B1a-B1b, p-well regions PW1-PW2, deep n-well DNW and p-type substrate 900 are grounded (0 Volts). A positive boosted program voltage V_{P} is applied to word line W1. Bit lines B2a-B16a and B2b-B16b are biased with a positive program counter-bias voltage V_{PC}. The voltages V_{P} and V_{PC} are selected in view of the thickness of the tunnel oxide of the NVM transistors to meet the operating characteristics described below.

Under the above-described conditions, NVM transistor M11 of byte B1 has a control gate biased to the boosted program voltage V_{P}, and a source region (i.e., bit line B1a) biased to ground (0 Volts). The p-well region PW1 in which NVM transistor M11 is located is also biased to ground (0 Volts). The net voltage applied across NVM transistor M11 is therefore equal to the boosted programming voltage V_{P} (i.e., V_{P}-0). The boosted programming voltage V_{P} is selected to be sufficient to cause electrons to tunnel from the channel region of NVM transistor M11 to the floating gate 911 of NVM transistor M11 under these bias conditions, thereby programming EEPROM cell C11 (i.e., raising the threshold voltage of NVM transistor M11). In one embodiment, the program voltage V_{P} is selected to have a value of about 15 Volts. Although the program voltage V_{P} is equal to the erase voltage V_{E} in the described embodiments, it is understood that this is not necessary, and that the program and erase voltages V_{P} and V_{E} can be varied to optimize the operation of memory array 800.

Under the bias conditions defined by table 1300, each of the remaining NVM transistors M12-M18 of byte B1, and each of the NVM transistors M21-M28 of byte B2 has a control gate biased to the boosted program voltage V_{P}, and a source region (bit line) biased to a positive program counter-bias voltage V_{PC}. As a result, the net voltage applied across NVM transistors M12-M18 and M21-M28 is equal to V_{P}-V_{PC}, which is less than the net voltage (V_{P}) applied across NVM transistor M11. As a result of the reduced net voltage applied across NVM transistors M12-M18 and M21-M28, the states of these NVM transistors M12-M18 and M21-M28 are not disturbed during the program operation of bit 1 of byte B1. That is, the net voltage (V_{P}-V_{PC}) applied across NVM transistors M12-M18 and M21-M28 is not large enough to result in substantial tunneling of electrons from the channel region to the floating gates of NVM transistors M12-M18 and M21-M28. In one embodiment, the program counter-bias voltage V_{PC} is selected to have a voltage of about 2 to 5 Volts, such that the net voltage V_{P}-V_{PC} is approximately equal to 10 to 13 Volts.

Note that NVM transistor M31 of byte B3 has a control gate (i.e., word line W2) biased to 0 Volts, and a source region (i.e., bit line B1a) biased to 0 Volts. Under these conditions, the state of NVM transistor M31 is not disturbed, because there is no net voltage difference developed across this NVM transistor.

Note that NVM transistors M32-M38 of byte B3 and NVM transistors M41-48 of byte B4 have control gates (i.e., word line W2) biased to 0 Volts, and source regions (i.e., bit lines B2a-B16a) biased to the program counter-bias voltage V_{PC}. As a result, the net voltage applied across each of NVM transistors M32-M38 and M41-M48 is equal to the program counter-bias voltage V_{PC}, which is less than the net voltage applied across either NVM transistors M12-M18 or NVM transistors M21-M28. More specifically, the voltage applied across each of NVM transistors M32-M38 and M41-M48 is about 2-5 Volts. Consequently, the states of NVM transistors M32-M38 and M41-M48 are not disturbed during the program operation of bit 1 of byte B1.

Note that EEPROM cells C11-C18 of byte B1 are written by performing an erase operation (which erases all of the NVM transistors M11-M18 of byte B1), followed by a program operation (which programs selected NVM transistors of byte B1). Further note that even if the NVM transistors M21-M28 of byte B2 were slightly erased during the erasing of byte B1, these NVM transistors M21-M28 of byte 2 would be slightly programmed during the programming of byte B1, such that the slight erase would effectively cancel the slight programming within the NVM transistors M21-M28 of byte 2.

FIG. 14 is a table 1400 that illustrates the voltages applied to memory array 800 to perform a read operation to the first row (i.e., bytes B1 and B2) of array 800, in accordance with one embodiment of the present invention. In this embodiment, each bit line pair is coupled to a corresponding sense amplifier circuit (not shown).

During the read operation defined by table 1400, the p-well regions PW1-PW2, deep n-well region DNW and p-type substrate 900 are grounded (0 Volts). The ground voltage (0 Volts) is also applied to select line SL2, thereby turning off the access transistors S31-S38 and S41-S48 of the second row. The ground voltage (0 Volts) is also applied to word line W2, thereby turning off the NVM transistors S31-S38 and S41-S48 of the second row.

The V_{DD} supply voltage is applied to select line SL1, thereby turning on the access transistors S11-S18 and of the first row. A first read control voltage V_{R1} is applied to the gates of NVM transistors M11-M18 and M21-M28 via word line W1. The first read control voltage V_{R1} is selected to be high enough to turn on NVM transistors that are in the erased state, but not high enough to turn on NVM transistors that are in the programmed state. In one embodiment, the first read control voltage V_{R1} is selected to have a value of about 1 Volt. In other embodiments, the first read control voltage V_{R1} has a value in the range of about 0 to 5 Volts.

A second read control voltage V_{R2} is applied to the source regions of NVM transistors M11-M18 and M21-M28 via corresponding bit lines B1a-B16a. In one embodiment, the second read control voltage V_{R2} is the same as the first read voltage V_{R1} (although this is not necessary). The drains of access transistors S11-S18 and S21-S28 are coupled to ground (0 Volts) through corresponding bit lines B1b-B16b. Under these bias conditions, a significant read current will flow through the memory cells of the first row that are in the erased (low threshold voltage) state. Conversely, no significant read current will flow through the memory cells of the first row that are in the programmed (high threshold voltage) state.

In the present embodiment, a sense amplifier circuit (not shown) is connected across each of the bit line pairs. Each sense amplifier determines whether a significant read current exists on the corresponding bit line pair during a read operation, and in response, provides an output data value representative of the programmed/erased state of the corresponding memory cell.

In an alternate embodiment, data is read from memory array 800 on a per byte (rather than per row) basis. In this embodiment, eight sense amplifiers are selectively coupled to the eight bit line pairs associated with a corresponding byte to be read during a read operation. For example, to read the first byte B1, bit line pairs B1a-B8a and B1b-B8b are selectively coupled to eight sense amplifiers, such that the programmed/erased states of NVM transistors M11-M18 may be detected. The bias voltages remain substantially the same as those provided in table 1400, except that bit lines B9a-B16a are coupled to ground (rather than the second read control voltage V_{R2}). Note that in this embodiment, bit lines B9a-B16a and B9b-B16b are not coupled to sense amplifiers while byte B1 is being read.

Note that the boosted erase voltage V_{E} is not applied across the gate dielectric layer of any of the access transistors S11-S18, S21-S28, S31-S38 and S41-S48 during erase operations. Similarly, the boosted program voltage V_{P} is not applied across the gate dielectric layer of any of the access transistors S11-S18, S21-S28, S31-S38 and S41-S48 during program operations. Consequently, these access transistors S11-S18, S21-S28, S31-S38 and S41-S48 do not require a thick gate dielectric layer, and may be fabricated using the same tunnel gate oxide layer used in NVM transistors M11-M18, M21-M28, M31-M38 and M41-M48.

Also note that the boosted erase voltage V_{E} and the boosted program voltage V_{P} are not applied to the drains of access transistors S11-S18, S21-S28, S31-S38 and S41-S48, or to the sources of NVM transistors M11-M18, M21-M28, M31-M38 and M41-M48 during erase or program operations. As a result, access transistors S11-S18, S21-S28, S31-S38 and NVM transistors M11-M18, M21-M28, M31-M38 and M41-M48 do not require large spacing at the source/drain diffusion contact regions.

Also note that within memory array 800, each column of EEPROM cells has a first bit line (e.g., bit line B1a) coupled to the sources of the NVM transistors in the column, and a second bit line coupled to the drains of the access transistors in the column. These bit line pairs provide low-resistance, shielded read paths between the EEPROM cells and the corresponding sense amplifiers, thereby facilitating fast read operations.

The above-described features of memory array 800 advantageously allows this array to be scaled to sub-0.35 micron processes.

Although the invention has been described in connection with several embodiments, it is understood that this invention is not limited to the embodiments disclosed, but is capable of various modifications, which would be apparent to one of ordinary skill in the art. Accordingly, the present invention is only limited by the following claims.

We claim:

1. A memory system comprising:
a first non-volatile memory cell having a first access transistor and a first non-volatile memory transistor, wherein the first access transistor has a source region that is continuous with a drain region of the first non-volatile memory transistor;
a second non-volatile memory cell having a second access transistor and a second non-volatile memory transistor, wherein the second access transistor has a source region that is continuous with a drain region of the second non-volatile memory transistor, and wherein the second non-volatile memory transistor has a source region that is continuous with a source region of the first non-volatile memory transistor;
a first bit line connected to a drain of the first access transistor and a drain of the second access transistor; and
a second bit line connected to the source regions of the first and second non-volatile memory transistors.

2. The memory system of claim 1, further comprising:
a first word line coupled to a control gate of the first non-volatile memory transistor;
a second word line coupled to a control gate of the second non-volatile memory transistor.
a first select line coupled to a control gate of the first access transistor; and
a second select line coupled to a control gate of the second access transistor.

3. The memory system of claim 1, further comprising:
a third non-volatile memory cell having a third access transistor and a third non-volatile memory transistor, wherein the third access transistor has a source region that is continuous with a drain region of the third non-volatile memory transistor;
a fourth non-volatile memory cell having a fourth access transistor and a fourth non-volatile memory transistor, wherein the fourth access transistor has a source region that is continuous with a drain region of the fourth non-volatile memory transistor, and wherein the fourth non-volatile memory transistor has a source region that is continuous with a source region of the third non-volatile memory transistor;
a third bit line connected to a drain of the third access transistor and a drain of the fourth access transistor; and
a fourth bit line connected to the source regions of the third and fourth non-volatile memory transistors.

4. The memory system of claim 3, further comprising a first well region and a second well region, each having a first conductivity type, wherein the first well region and the second well region are located within, and isolated by, a third well region having a second conductivity type, opposite the first conductivity type, wherein the first and second non-volatile memory cells are located in the first well region, and wherein the third and fourth non-volatile memory cells are located in the second well region.

5. The memory system of claim 3, further comprising:
a first word line coupled to a control gate of the first non-volatile memory transistor and a control gate of the third non-volatile memory transistor;
a second word line coupled to a control gate of the second non-volatile memory transistor and a control gate of the fourth non-volatile memory transistor;
a first select line coupled to a control gate of the first access transistor and a control gate of the third access transistor; and
a second select line coupled to a control gate of the second access transistor and a control gate of the fourth access transistor.

6. The memory system of claim 5, further comprising a first well region and a second well region, each having a first conductivity type, wherein the first well region and the second well region are located within, and isolated by, a third well region having a second conductivity type, opposite the first conductivity type, wherein the first and second non-volatile memory cells are located in the first well region, and wherein the third and fourth non-volatile memory cells are located in the second well region.

7. The memory system of claim 1, wherein the first access transistor and the first non-volatile memory transistor each includes:
a gate dielectric layer;
a first gate layer located over the gate dielectric layer;
an inter-gate dielectric layer located over the first gate layer; and
a second gate layer located over the inter-gate dielectric layer.

8. The memory system of claim 7, wherein the first gate layer is isolated from the second gate layer in the first non-volatile memory transistor, and wherein the first gate layer is electrically connected to the second gate layer in the first access transistor.

9. The memory system of claim 7, wherein the first gate layer is isolated from the second gate layer in the first non-volatile memory transistor, and wherein the first gate layer is isolated from the second gate layer in the first access transistor.

10. The memory system of claim 1, wherein the first access transistor and the first non-volatile memory transistor include identical gate and dielectric layers.

11. The memory system of claim 1, wherein the drain regions and the source regions of the first access transistor, the first non-volatile memory transistor, the second access transistor and the second non-volatile memory transistor are laid out along a first line, wherein the first and second bit lines extend in parallel with the first line.

12. The memory system of claim 11, wherein the source regions of the first and second non-volatile memory transistors extend away from the first line to a location wherein the second bit line is connected to the source regions of the first and second non-volatile memory transistors.

13. The memory system of claim 1, wherein the first and second access transistors comprise control gates fabricated from a first polysilicon layer and wherein the first and second non-volatile memory transistors comprise floating gates fabricated from the first polysilicon layer.

14. The memory system of claim 13, wherein the first and second access transistors and the first and second non-volatile memory transistors each include a gate dielectric layer having the same thickness.

15. The memory system of claim 1, wherein the first and second non-volatile memory transistors comprise control gates fabricated from a second polysilicon layer.

16. A memory system comprising:
an array of non-volatile memory cells arranged in a plurality of rows and columns, wherein the array includes a first sub-array that includes the non-volatile memory cells present in a first plurality of columns of the array, and a second sub-array that includes the non-volatile memory cells present in a second plurality of columns of the array;
a first well region of a first conductivity type, wherein the first sub-array is fabricated in the first well region;
a second well region of the first conductivity type, wherein the second sub-array is fabricated in the second well region; and
a deep well region of a second conductivity type, opposite the first conductivity type, wherein the first and second wells are located in, and isolated by, the deep well region.

17. The memory system of claim 16, wherein each of the non-volatile memory cells of the array include an access transistor and a non-volatile memory transistor.

18. The memory system of claim 16, wherein the first plurality columns and the second plurality of columns each includes a first number of columns, wherein the first number corresponds with a byte width of the array.

19. A method of operating a row of non-volatile memory cells, each having an access transistor and a non-volatile memory transistor, the method comprising performing an erase operation by:
applying a first erase voltage to a control gate of each non-volatile memory transistor in the row;
erasing a first set of non-volatile memory cells in the row by applying a second erase voltage to a first well region, wherein the first set of non-volatile memory cells is fabricated in the first well region, and wherein the first and second erase voltages induce a tunneling current in each non-volatile memory transistor in the first set of non-volatile memory cells; and
inhibiting erasing in a second set of non-volatile memory cells in the row by applying a third erase voltage to a second well region, wherein the second set of non-volatile memory cells is fabricated in the second well region, and wherein the first and third erase voltages are insufficient to induce a tunneling current in each non-volatile memory transistor in the second set of non-volatile memory cells.

20. The method of claim 19, wherein the first erase voltage is ground, the second erase voltage is a positive boosted voltage, and the third erase voltage is a voltage between ground and the positive boosted voltage.

21. The method of claim 19, further comprising performing a program operation by:
applying a first program voltage to a control gate of each non-volatile memory transistor in the row;
programming a third set of non-volatile memory cells in the row by applying a second program voltage to a source region of each non-volatile memory transistor in the third set of non-volatile memory cells, wherein the first and second program voltages induce a tunneling current in each non-volatile memory transistor in the third set of non-volatile memory cells; and
inhibiting programming in a fourth set of non-volatile memory cells in the row by applying a third program voltage to a source region of each non-volatile memory transistor in the fourth set of non-volatile memory cells, wherein the first and third program voltage are insufficient to induce a tunneling current in each non-volatile memory transistor in the fourth set of non-volatile memory cells.
